(19) United States
(12) Patent Application Publication
(10) Pub. No.: US 2025/0079153 A1
(43) Pub. Date: Mar. 6, 2025

(54) SUBSTRATE PROCESSING METHOD AND SUBSTRATE PROCESSING DEVICE

(71) Applicant: SCREEN Holdings Co., Ltd., Kyoto (JP)

(72) Inventor: Noritake SUMI, Kyoto (JP)

(21) Appl. No.: 18/679,593

(22) Filed: May 31, 2024

(30) Foreign Application Priority Data
Aug. 28, 2023 (JP) 2023-138192

(51) Int. Cl. H01L 21/02; B08B 3/10; B08B 7/00; H01L 21/67; H01L 21/687

(52) U.S. Cl. CPC H01L 21/02101; B08B 3/10; B08B 7/0021; H01L 21/67034; H01L 21/68728

(57) ABSTRACT

In a substrate processing method and a substrate processing device, a processing fluid is dissolved into a liquid film which is formed on a substrate. A surface tension of the liquid film decreases in a pressure boosting period during which the pressure is boosted by supplying the processing fluid to a processing chamber. Therefore, part of the liquid film flows down from the substrate and the liquid film is thinned to a certain extent. Here, a reduction amount of the film thickness drastically increases by applying the vibration to the substrate in the pressure boosting period, and film thinning is promoted. Thereafter, the processing fluid in the supercritical state contacts the thinned liquid film, whereby the substrate is dried.

### CROSS REFERENCE TO RELATED APPLICATION

The disclosure of Japanese Patent Application No. 2023-138192 filed on Aug. 28, 2023 including specification, drawings and claims is incorporated herein by reference in its entirety.

### BACKGROUND OF THE INVENTION

### 1. Field of the Invention

This invention relates to a technique for drying a substrate in a processing chamber and particularly to a process for processing a substrate covered with a liquid film by a processing fluid in a supercritical state.

### 2. Description of the Related Art

Processing steps of various substrates such as semiconductor substrates and glass substrates for display device include processing of a substrate surface by various processing fluids. A wet processing using a liquid such as a chemical or a rinse liquid as a processing fluid has been conventionally widely performed. In recent years, a processing using a processing fluid in a supercritical state has also been put to practical use to dry the substrate after this wet processing. Particularly, this is useful in a dry processing of a substrate having a pattern formed surface formed with a fine pattern. This is because the processing fluid in the supercritical state has a property of having a lower surface tension than liquids and entering deep into gaps of the pattern. By using this processing fluid, the dry processing can be efficiently performed. Further, it is also possible to reduce an occurrence risk of pattern collapse due to a surface tension during drying.

For example, in a substrate processing device described in JP 2022-103636A, a substrate having a liquid film made of IPA (isopropyl alcohol), which is an example of an “organic solvent” of the invention, is dried by carbon dioxide (processing fluid) in a supercritical state. This liquid film is formed by filling the IPA on a surface of the substrate. Thus, the surface of the substrate is maintained in a state wetted with the IPA. The substrate maintained in the liquid-filled state is conveyed to a substrate drying device corresponding to an example of a “substrate processing device” of the invention, and a dry processing by the processing fluid in the supercritical state is performed.

### SUMMARY OF INVENTION

In the substrate processing device, the IPA covering the substrate is replaced by the processing fluid in the supercritical state by filling the processing fluid in the supercritical state in a processing chamber. The IPA liberated from the surface of the substrate is discharged from the processing chamber together with the processing fluid in a state dissolved in the processing fluid. In this way, the supercritical dry processing is subjected to the substrate. Therefore, it is thought to be useful to thin the liquid film before contact with the processing fluid in the supercritical state to shorten a time required for the supercritical dry processing. However, conventionally, a processing time has not been shortened by the above approach.

This invention was developed in view of the above problem and aims to shorten a drying time in a substrate processing method and a substrate processing device for drying a substrate having a liquid film of an organic solvent formed in a liquid-filled state on a surface by a processing fluid in a supercritical state.

One aspect of this invention is directed to a substrate processing method for drying a substrate having a liquid film of an organic solvent formed in a liquid-filled state on a surface by a processing fluid in a supercritical state. The method comprises: (a) accommodating the substrate into a processing chamber; (b) boosting the processing chamber from an atmospheric pressure to a first pressure by supplying the processing fluid to the processing chamber, a subcritical state being reached at the first pressure; (c) boosting the processing chamber to a second pressure by supplying the processing fluid to the processing chamber boosted to the first pressure, the supercritical state being reached at the second pressure; and (d) reducing a film thickness of the liquid film while maintaining the liquid-filled state by applying vibration to the substrate in a pressure boosting period until the processing chamber enters the supercritical state from start of the operation (b).

Other aspect of the invention is a substrate processing device for drying a substrate having a liquid film of an organic solvent formed in a liquid-filled state on a surface by a processing fluid in a supercritical state. The device comprises: a processing chamber configured to accommodate the substrate; a fluid supplier configured to supply the processing fluid to the processing chamber; a vibration applicator configured to apply vibration to the substrate accommodated in the processing chamber; and a controller configured to control the fluid supplier such that the processing chamber is boosted to a second pressure, the supercritical state being reached at the second pressure, by way of a first pressure, a subcritical state being reached at the first pressure, by supplying the processing fluid to the processing chamber in an atmospheric pressure state and configured to control the vibration applicator to apply the vibration to the substrate while the processing chamber is boosted from an atmospheric pressure to the first pressure by applying the vibration to the substrate in a pressure boosting period until the processing chamber enters the supercritical state from start of the supply of the processing fluid.

In the invention thus configured, the processing fluid is dissolved into the liquid film and a surface tension of the liquid film decreases in the pressure boosting period during which the pressure is boosted by supplying the processing fluid to the processing chamber. Therefore, part of the liquid film flows down from the substrate and the liquid film is thinned to a certain extent. Here, a reduction amount of the film thickness drastically increases by applying the vibration to the substrate in this pressure boosting period, and film thinning is promoted. Thereafter, the processing fluid in the supercritical state contacts the thinned liquid film, whereby the substrate is dried.

As described above, according to the invention, a drying time can be shortened by applying vibration to a substrate in a pressure boosting period.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a drawing showing a schematic configuration of a substrate processing system equipped with a first embodiment of a substrate processing device according to the present invention.

FIG. 2A is a side view showing the overall configuration of the wet processing device.

FIG. 2B is a diagram showing the operation of the wet processing device.

FIG. 3 is a side view showing the configuration of the supercritical processing device.

FIG. 4 is a perspective view showing the structure of the support tray.

FIG. 5 is diagrams schematically showing the configuration and operation of the chuck pin.

FIG. 6 is a flow chart outlining the processing performed by the substrate processing system according to the first embodiment.

FIG. 7 is a chart showing a pressure change in the processing chamber, operations of support pins and an inside of the pattern.

FIG. 8A is a diagram schematically showing a problem occurring in the liquid film after the liquid film formation processing.

FIG. 8B is a diagram schematically showing how the above problem is solved by vibration application.

FIG. 9 is a diagram showing a second embodiment of the substrate processing device according to the invention.

FIG. 10 is a diagram showing a third embodiment of the substrate processing device according to the invention.

### DETAILED DESCRIPTION OF THE PREFERRED EMBODIMENTS

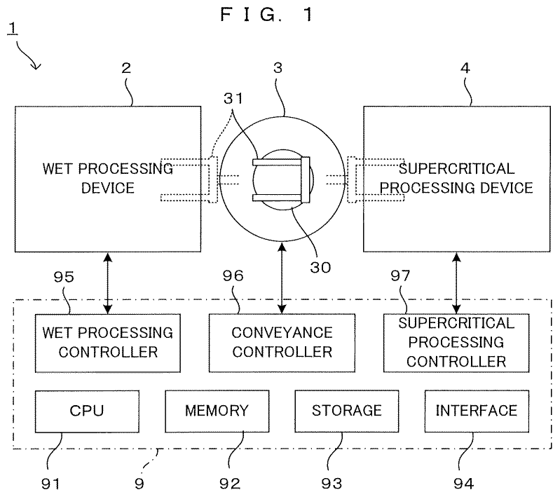

FIG. 1 is a drawing showing a schematic configuration of a substrate processing system equipped with a first embodiment of a substrate processing device according to the present invention. This substrate processing system 1 is a processing system for wet-processing various substrates such as semiconductor wafers by supplying a processing fluid to the upper surfaces of the substrates and, thereafter, drying the substrates. The substrate processing system 1 has a suitable system configuration to carry out a substrate processing method according to the invention. That is, the substrate processing system 1 is provided with a wet processing device 2, a substrate conveying device 3 and a control device 9.

The wet processing device 2 performs a predetermined wet processing by receiving a substrate to be processed. Contents of the processing are not particularly limited. The wet processing includes a development processing, a cleaning processing and the like. After performing the development processing and the like, a liquid-filled state filled with an organic solvent such as an IPA liquid is created on a pattern formed surface of the substrate. The substrate conveying device 3 carries out and conveys the substrate from the substrate processing device 2 with the liquid-filled state maintained, and carries the substrate into the supercritical processing device 4. The supercritical processing device 4 corresponds to the substrate processing device according to the present invention and performs a dry processing (supercritical dry processing) using a processing fluid in a supercritical state for the carried-in substrate. These are installed in a clean room. Therefore, the substrate conveying device 3 conveys the substrate S in an air atmosphere and under an atmospheric pressure.

The control device 9 realizes a predetermined process by controlling these components of the device. For this purpose, the control device 9 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 performs information exchange with a user and an external device. Operations of the device to be described later are realized by the CPU 91 causing each component of the device to perform a predetermined operation by executing the control program written in the storage 93 in advance.

The CPU 91 executes a predetermined control program, whereby functional blocks such as a wet processing controller 95 for controlling the operation of the wet processing device 2, a conveyance controller 96 for controlling the operation of the substrate conveying device 3 and a supercritical processing controller 97 for controlling the operation of the supercritical processing device 4 are realized by software in the control device 9. Note that each of these functional blocks may be at least partially configured by dedicated hardware.

Here, various substrates such as semiconductor wafers, glass substrates for photomask, glass substrates for liquid crystal display, glass substrates for plasma display, substrates for FED (Field Emission Display), optical disk substrates, magnetic disk substrates and magneto-optical disk substrates can be applied as the “substrate” in this embodiment. The substrate processing device used in processing semiconductor wafers is mainly described as an example with reference to the drawings below. However, application to the processing of various substrates illustrated above is also possible. Further, various shape of the substrate are also available.

A substrate S used as an example in the following description has a circuit pattern, etc. formed only on one main surface thereof. Here, a surface corresponding to the main surface with the circuit pattern, etc. will be called a “front surface,” and a main surface on the opposite side without a circuit pattern, etc. will be called a “back surface.” Furthermore, a surface of the substrate S facing downward will be called a “lower surface,” and a surface of the substrate S facing upward will be called an “upper surface.” In the example descried below, the front surface corresponds to the upper surface.

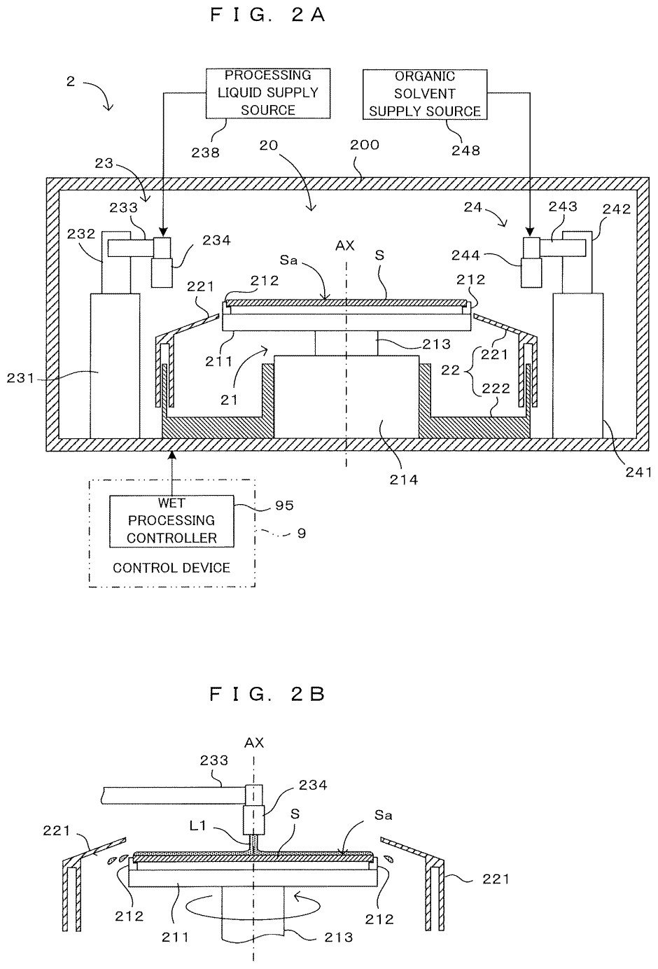

FIGS. 2A and 2B are diagrams showing a configuration example of the wet processing device. More specifically, FIG. 2A is a side view showing the overall configuration of the wet processing device, and FIG. 2B is a diagram showing the operation of the wet processing device. This wet processing device 2 is a device for processing the substrate by supplying the processing fluid to the upper surface of the substrate S. The operation of the wet processing device 2 is controlled by the wet processing controller 95 of the control device 9.

The wet processing device 2 performs a surface processing of the substrate S and a wet processing such as washing by supplying the processing liquid to the upper surface (pattern formed surface) Sa of the substrate S. For this purpose, the wet processing device 2 is provided with a substrate holder 21, a splash guard 22 and processing liquid suppliers 23, 24 inside the processing chamber 200. The operations of these are controlled by the wet processing controller 95 provided in the control device 9. The substrate holder 21 includes a disk-like spin chuck 211 having a diameter nearly equal to that of the substrate S, and a plurality of chuck pins 212 are provided on a peripheral edge part of the substrate S. The spin chuck 211 can hold the substrate S in a horizontal posture while separating the substrate S from the upper surface of the spin chuck 211 by the chuck pins 212 supporting the substrate S in contact with a peripheral edge part of the substrate S.

The spin chuck 211 is so supported that the upper surface thereof is horizontal by a rotary support shaft 213 extending downward from a central part of the lower surface of the spin chuck 211. The rotary support shaft 213 is rotatably supported by a rotating mechanism 214 mounted in a bottom part of the processing chamber 200. The rotating mechanism 214 includes an unillustrated built-in rotary motor. The rotary motor rotates in response to a control command from the control device 9, whereby the spin chuck 211 directly coupled to the rotary support shaft 213 rotates about the axis of rotation AX indicated by a dashed-dotted line. In FIGS. 2A and 2B, an up-down direction is a vertical direction. In this way, the substrate S is rotated about the axis of rotation AX while being held in the horizontal posture.

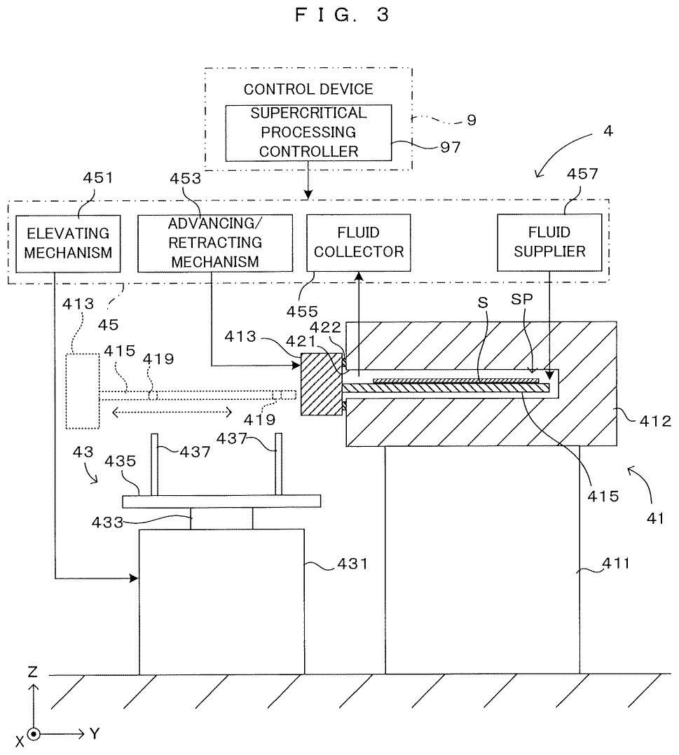

The splash guard 22 is provided to laterally surround the substrate holder 21. The splash guard 22 includes a substantially tubular cup 221 provided to cover the peripheral edge part of the spin chuck 211 and a liquid receiver 222 provided below an outer peripheral part of the cup 221. The cup 211 is raised and lowered in response to a control command from the control device 9. The cup 221 is raised and lowered between a lower position where an upper end part of the cup 221 is lowered to below the peripheral edge part of the substrate S held by the spin chuck 211 as shown by solid lines in FIG. 3 and an upper position where the upper end part of the cup 221 is located above the peripheral edge part of the substrate S as shown by dotted lines in FIG. 3.

As shown by solid lines in FIG. 2A, when the cup 221 is at the lower position, the substrate S held by the spin chuck 211 is exposed to the outside of the cup 221. Thus, the cup 221 is, for example, prevented from becoming an obstacle when the substrate S is carried to and from the spin chuck 211.

Further, as indicated by dotted lines in FIG. 2B, the cup 221 surrounds the peripheral edge part of the substrate S held by the spin chuck 211 when being at the upper position. In this way, the processing liquid shaken off from the peripheral edge part of the substrate S during liquid supply to be described later is prevented from scattering in the chamber 200, and the processing liquid can be reliably collected. That is, by the rotation of the substrate S, droplets of the processing liquid shaken off from the peripheral edge part of the substrate S adhere to the inner wall of the cup 221, flow down and are finally gathered and collected by the liquid receiver 222 arranged below the cup 221. To individually collect a plurality of processing liquids, cups may be concentrically provided at a plurality of levels.

The processing liquid supplier 23 is structured such that a nozzle 234 is attached to the tip of an arm 233 horizontally extending from a rotary support shaft 232 provided rotatably with respect to a base 231 fixed in the processing chamber 200. The rotary support shaft 232 rotates in response to a control command from the control device 9, whereby the arm pivots and the nozzle 234 on the tip of the arm 233 moves between a retreated position (FIG. 2A) retracted laterally from above the substrate S and a processing position (FIG. 2B) above the substrate S.

The nozzle 234 is connected to a processing liquid supply source 238. If an appropriate processing liquid is sent out from the processing liquid supply source 238, the processing liquid is discharged toward the substrate S from the nozzle 234. By supplying the processing liquid L1 from the nozzle 234 positioned above a center of rotation of the substrate S while rotating the substrate S by the rotation of the spin chuck 211 at a relatively low speed, an upper surface Sa of the substrate S is processed by the processing liquid L1. Liquids having various functions such as developers, etching liquids, cleaning liquids and rinsing liquids can be used as the processing liquid, and a composition of the processing liquid is arbitrary. Further, the processing may be performed with a plurality of types of processing liquids combined.

Another processing liquid supplier 24 also has a configuration corresponding to the first processing liquid supplier 23 described above. That is, processing liquid supplier 24 includes a base 241, a rotary support shaft 242, an arm 243, a nozzle 244 and the like, and the configurations of these are the same as those of the corresponding components of the first processing liquid supplier 23. The rotary support shaft 242 rotates in response to a control command from the control device 9, whereby the arm 243 pivots. The nozzle 244 on the tip of the arm 243 supplies a processing liquid to the upper surface Sa of the substrate S.

In this wet processing device 2, the second processing liquid supplier 24 is used for the purpose of forming a liquid film for dry prevention on the substrate S after the wet processing. That is, the substrate S after the wet processing is conveyed to the supercritical processing device 4 and receives a supercritical drying processing. To prevent the surface of the substrate S from being exposed and oxidized during conveyance and prevent the collapse of the fine pattern formed on the surface, the substrate S is conveyed with the surface thereof covered with a puddle-like liquid film.

A substance having a lower surface tension than water, which is a main component of a processing liquid used in a cleaning processing, e.g. an organic solvent such as isopropyl alcohol (IPA) or acetone, is used as the liquid for constituting the liquid film. These organic solvents are supplied from an organic solvent supply source 248.

Although two processing liquid suppliers are provided in the wet processing device 2 here, the number, structures and functions of the processing liquid suppliers are not limited to these. For example, only one processing liquid supplier may be provided or three or more processing liquid suppliers may be provided. Further, one processing liquid supplier may include a plurality of nozzles. For example, a plurality of nozzles may be provided on the tip of one arm. Further, the processing liquid is not only discharged with the nozzle positioned at the predetermined position as described above, but also may be, for example, discharged while the nozzle is scanned and moved along the upper surface Sa of the substrate S.

Referring back to FIG. 1, description is continued. The substrate conveying device 3 is provided with a conveyor robot 30 provided with a hand 31 on the tip of a telescopic/rotatable arm. The hand 31 can support the substrate by partially contacting the lower surface of the substrate and, as shown by dotted lines in FIG. 1, is movable toward and away from both the wet processing device 2 and the supercritical processing device 4. In this way, the substrate can be carried in and out from each of the wet processing device 2 and the supercritical processing device 4. The operation of the conveyor robot 30 is controlled by the conveyance controller 96 of the control device 9. Many techniques are known as conveyor robots of this type. Since one of those can be appropriately selected and used also in this embodiment, detailed description is omitted.

FIG. 3 is a side view showing the configuration of the supercritical processing device. The supercritical processing device 4 corresponds to the first embodiment of the substrate processing device according to the present invention, and is a device for applying a drying processing using a processing fluid in a supercritical state to the substrate S after the wet processing. More specifically, the supercritical processing device 4 is a device for finally bringing the substrate S to a dry state by discharging the processing fluid after receiving the substrate S after the wet processing and replacing the liquid remaining on the substrate S by the processing fluid in the supercritical state.

The supercritical processing device 4 is provided with a processing unit 41 and a transfer unit 43 provided in the processing chamber 400 and a supply unit 45. The processing unit 41 serves as an executor of the supercritical drying processing. The transfer unit 43 receives the substrate S after the wet processing conveyed by the substrate conveying device 3, carries the substrate S into the processing unit 41 and transfers the processed substrate S from the processing unit 41 to the conveyor device 3. The supply unit 45 supplies chemical substances, power, energy and the like necessary for the processing to the processing unit 41 and the transfer unit 43. These operations are controlled by the control device 9, particularly by the supercritical processing controller 97.

The processing unit 41 is structured such that a processing chamber 412 is mounted on a pedestal 411. The processing chamber 412 is configured by a combination of several metal blocks and the inside thereof is hollow and constitutes a processing space SP. The substrate S to be processed is carried into the processing space SP and processed. A slit-like opening 421 elongated in the X direction is formed in a side surface on the (−Y) side of the processing chamber 412. The processing space SP and an outside space communicate via the opening 421. A cross-sectional shape of the processing space SP is substantially the same as an opening shape of the opening 421. That is, the processing space SP is a hollow having a cross-sectional shape long in the X direction and short in the Z direction and extending in the Y direction.

A lid member 413 is provided to close the opening 421 on a side surface on the (−Y) side of the processing chamber 412. The lid member 413 closes the opening 421 of the processing chamber 412, whereby an airtight processing container is configured. In this way, the substrate S can be processed under a high pressure in the processing space SP inside. A support tray 415 in the form of a flat plate is mounted in a horizontal posture on a side surface on the (+Y) side of the lid member 413. The upper surface of the support tray 415 serves as a support surface, on which the substrate S can be placed. The lid member 413 is supported horizontally movably in the Y direction by an unillustrated supporting mechanism.

The lid member 413 is movable toward and away from the processing chamber 412 by an advancing/retracting mechanism 453 provided in the supply unit 45. Specifically, the advancing/retracting mechanism 453 includes a linear motion mechanism such as a linear motor, a linear motion guide, a ball screw mechanism, a solenoid or an air cylinder. Such a linear motion mechanism moves the lid member 413 in the Y direction. The advancing/retracting mechanism 453 operates in response to a control command from the control device 9.

If the lid member 413 is separated from the processing chamber 412 by moving in the (−Y) direction and the support tray 415 is pulled out from the processing space SP to outside via the opening 421 as indicated by a dotted line, the support tray 415 becomes accessible. That is, the substrate S can be placed on the support tray 415 and the substrate S placed on the support tray 415 can be taken out. On the other hand, by a movement of the lid member 413 in the (+Y) direction, the support tray 415 is accommodated into the processing space SP. If the substrate S is placed on the support tray 415, the substrate S is carried into the processing space SP together with the support tray 415.

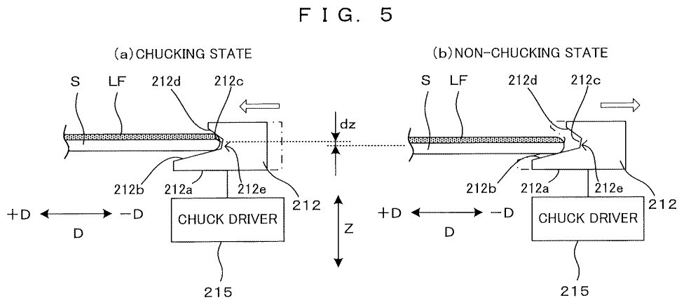

FIG. 5 is a perspective view showing the structure of the support tray. The support tray 415 includes a tray member 416 and a plurality of support pins 417. The tray member 415 is structured such that a recess 418 corresponding to the planar size of the substrate S, more specifically, having a diameter slightly larger than that of the circular substrate S, is provided in the horizontal and flat upper surface of a flat plate-like structure.

The recess 418 partially extends to the side surface of the tray member 416. That is, the side wall surface of the recess 48 is not circular, but partially cut. Thus, parts of a bottom surface 418a of the recess 418 are directly connected to the side surface in these cut parts. In this example, such cut parts are provided on both X side end parts and a (+Y) side end part of the support tray 415, and the bottom surface 418a is directly connected to the side surface in these parts.

Further, through holes 419, through which lift pins 437 are inserted, are perforated at positions of the bottom surface 418a corresponding to the lift pins 437 of the transfer unit 43. By lifting and lowering the lift pins 437 through the through holes 419, a state where the substrate S is accommodated in the recess 418 and a state where the substrate S is lifted up from the recess 418 are realized.

The plurality of support pins 417 are provided on a peripheral edge part of the recess 418. The number of the support pins 417 is arbitrary, but three or more support pins 417 are desirable to stably support the substrate S. In this embodiment, three support pins 417 are mounted on the tray member 416 to surround the bottom surface 418a in a plan view from above.

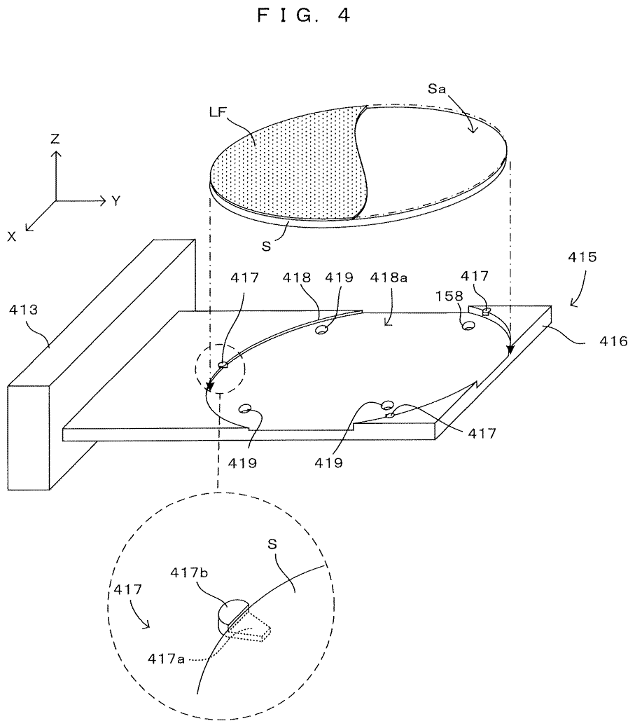

Any of the plurality of support pins 417 has the same configuration. Accordingly, the configuration of one support pin 417 is described below and each part of the other support pins 417 is denoted by the same reference sign and not described. As shown in FIG. 5, the support pin 417 has a tray contact surface 417a. This tray contact surface 417a is movable along a radial direction D on the upper surface of the tray member 416. In the support pin 417, a lower contact surface 417b is provided above the tray contact surface 417a. The lower contact surface 417b is inclined downward in a (+D) direction toward a center line BX. Here, the “center line BX” means a vertical line passing through a center of the recess 418 as shown in FIG. 4, and passes through a center of the substrate S when the substrate S is chucked by the plurality of support pins 417 as described later.

A curved contact surface 417c is provided to extend upward from an end part on a (−D) direction side of this lower contact surface 417b. This curved contact surface 417c is finished into a curved surface facing toward the side of the center line BX. Further, an upper contact surface 417d extends upward from an upper end of the curved contact surface 417c. This upper contact surface 417d is inclined upward in the (+D) direction toward the center line BX. More particularly, as shown in FIG. 5, the curved contact surface 417c is directly connected to the upper and lower contact surfaces 417d, 417b while being arranged between the upper and lower contact surfaces 417d, and 417b. Therefore, if a substrate contact part 417d, in which the upper contact surface 417d, the curved contact surface 417b and the lower contact surface 417b are connected and in contact with the substrate S, is viewed from a horizontal direction orthogonal to the radial direction D, the substrate contact part 417e is substantially C-shaped. That is, the support pin 417 can be reciprocated along the radial direction D with the substrate contact part 417e facing the center line BX.

The support pin 417 is connected to a pin driver 417f. The pin driver 417f moves the support pin 417 in the radial direction D in response to a command from the supercritical processing controller 97. For example, when the substrate S is transferred to and from the substrate conveying device 3, the pin driver 417f moves the support pin 417 in the (−D) direction and positions the support pin 417 at a non-chucking position (corresponding to an example of a “releasing position” of the invention) as shown in FIG. 5(b). At this time, the curved contact surface 417c and the upper contact surface 417d are separated from the center line BX by a distance slightly longer than a radius of the substrate S. On the other hand, the lower contact surface 417b is located below the substrate S. Therefore, as shown in FIG. 5(b), the substrate S is supported at a position of the lower contact surface 417b separated toward the (+D) direction side from the curved contact surface 417c only by the lower contact surface 417b.

On the other hand, in chucking the substrate S, the pin driver 417f moves the support pin 417 in the (+D) direction and positions the support pin 417 at a chucking position (corresponding to an example of a “sandwiching position” of the invention) as shown in FIG. 5(a). By moving the support pin 417 from the non-chucking position to the chucking position in this way, the support position of the substrate S by the lower contact surface 417b is shifted in the (−D) direction. When the movement of this support pin 417 to the chucking position is completed, the substrate S is supported by the lower contact surface 417b, the curved contact surface 417c and the upper contact surface 417d. That is, substrate chucking is completed.

In releasing the chucking of the substrate S, the support pin 417 is moved in a procedure reverse from the above procedure and the support position of the substrate S by the lower contact surface 417b is shifted in the (+D) direction.

Further, by moving the support position of the substrate S by the lower contact surface 417b in the radial direction D, the height position of the substrate S in a vertical direction Z is displaced by a distance dz. Accordingly, if the supercritical processing controller 97 gives a reciprocal movement command to the pin driver 417f, the support pin 417 is reciprocated in the radial direction D and lifting and lowering movements of the substrate S are synchronously repeated. That is, vibration in the vertical direction can be applied to the substrate S. In this embodiment, the aim of the invention is achieved utilizing this vibration application. This point is described in detail later together with the description of the operation of the substrate processing system 1.

The processing space SP is closed by the lid member 413 moving in the (+Y) direction and closing the opening 421. A sealing member 422 is provided between the side surface on the (+Y) side of the lid member 413 and the side surface on the (−Y) side of the processing chamber 412 to hold the processing space SP airtight. The sealing member 422 is, for example, made of rubber. Further, the lid member 413 is fixed to the processing chamber 412 by an unillustrated lock mechanism. As just described, in this embodiment, the lid member 413 is switched between a closing state (solid line) for sealing the processing space SP by closing the opening 421 and a separated state (dotted line) where the lid member 413 is largely separated from the opening 421 to enable the substrate S to be taken in and out.

With the airtight state of the processing space SP ensured, the substrate S is processed in the processing space SP. In this embodiment, a fluid supplier 457 provided in the supply unit 45 sends out a processing fluid of a substance usable in the supercritical processing, e.g. carbon dioxide, as the processing fluid and further brings the processing fluid into a supercritical state by pressurizing the processing fluid in the processing chamber 412. The processing fluid is supplied in a gas or liquid state to the processing unit 41. Carbon dioxide is a chemical substance suitable for the supercritical drying processing in having a property of entering the supercritical state at relatively low temperature and low pressure and dissolving into an organic solvent often used in substrate processing well. At a critical point at which carbon dioxide enters the supercritical state, an atmospheric pressure (critical pressure) is 7.38 MPa and a temperature (critical temperature) is 31.1° C.

If the processing fluid is filled into the processing space SP and the inside of the processing space SP reaches suitable temperature and pressure, the processing space SP is filled with the processing fluid in the supercritical state. In this way, the substrate S is processed by the processing fluid in the supercritical state in the processing chamber 412. The supply unit 45 is provided with a fluid collector 455, and the fluid after the processing is collected by the fluid collector 455. The fluid supplier 457 and the fluid collector 455 are controlled by the supercritical processing controller 97.

The processing space SP has a shape and a volume capable of receiving the support tray 415 and the substrate S supported by the support tray 415. That is, the processing space SP has a substantially rectangular cross-sectional shape wider than a width of the support tray 415 in a horizontal direction and having a height larger than that of the support tray 415 and substrate S combined in the vertical direction, and has a depth capable of receiving the support tray 415. As just described, the processing space SP has a shape and a volume enough to receive the support tray 415 and the substrate S. Gaps between the support tray 415 and the substrate S and the inner wall surface of the processing space SP are tiny. Therefore, the amount of the processing fluid necessary to fill the processing space SP can be relatively small.

The fluid supplier 457 supplies the processing fluid to the processing space SP on a side further in the (+Y) direction than the end part on the (+Y) side of the substrate S. On the other hand, the fluid collector 455 discharges the processing fluid flowing in a space above the substrate S and a space below the support tray 415, out of the processing space SP, on a side further in the (−Y) direction than the end part on the (−Y) side of the substrate S. In this way, laminar flows of the processing fluid from the (+Y) side toward the (−Y) side are respectively formed above the substrate S and below the support tray 415 in the processing space SP.

The supercritical processing controller 97 of the control device 9 specifies the pressure and temperature in the processing space SP based on a detection result of an unillustrated detector and controls the fluid supplier 457 and the fluid collector 455 based on that result. In this way, the supply of the processing fluid into the processing space SP and the discharge of the processing fluid from the processing space SP are properly managed and the pressure and temperature in the processing space SP are adjusted according to a processing recipe determined in advance.

The transfer unit 43 is in charge of the transfer of the substrate S between the substrate conveying device 3 and the support tray 415. For this purpose, the transfer unit 43 is provided with a body 431, an elevating member 433, a base member 435 and a plurality of lift pins 437. The elevating member 433 is a columnar member extending in the Z direction, and supported movably in the Z direction with respect to the body 431 by an unillustrated supporting mechanism. The base member 435 having a substantially horizontal upper surface is mounted atop the elevating member 433. The plurality of lift pins 437 stand up from the upper surface of the base member 435. The respective lift pins 437 support the substrate S in a horizontal posture from below by the contact of upper end parts thereof with the lower surface of the substrate S. Three or more lift pins 437 having the upper end parts at the same height are desirably provided to stably support the substrate S in the horizontal posture.

The elevating member 433 is made movable up and down by an elevating mechanism 451 provided in the supply unit 45. Specifically, the elevating mechanism 451 includes a linear motion mechanism such as a linear motor, a linear motion guide, a ball screw mechanism, a solenoid or an air cylinder, and such a linear motion mechanism moves the elevating member 433 in the Z direction. The elevating mechanism 451 operates in response to a control command from the control device 9.

The base member 435 is moved up and down by upward and downward movements of the elevating member 433, and the plurality of lift pins 437 move up and down integrally with the base member 435. In this way, the transfer of the substrate S is realized between the transfer unit 43 and the support tray 415. More specifically, as shown by dotted lines in FIG. 4, the substrate S is transferred with the support tray 415 pulled out to the outside of the chamber. For this purpose, the support tray 415 is provided with through holes 419, through which the lift pins 437 are inserted. If the base member 435 is raised, the upper ends of the lift pins 437 reach above the upper surface of the support tray 415 through the through holes 419. In this state, the substrate S conveyed by the conveyor robot 30 is transferred from the hand 31 of the conveyor robot 30 to the lift pins 437. By lowering the lift pins 437, the substrate S is transferred from the lift pins 437 to the support tray 415. The substrate S can be carried out by a procedure opposite to the above one. Note that, in this embodiment, the plurality of support pins 417 are positioned at the releasing position when the substrate S is carried in and out. On the other hand, other than that, the plurality of support pins 417 are positioned at the sandwiching position. However, in a film thinning processing to be described next, the releasing position and the sandwiching position are alternately switched.

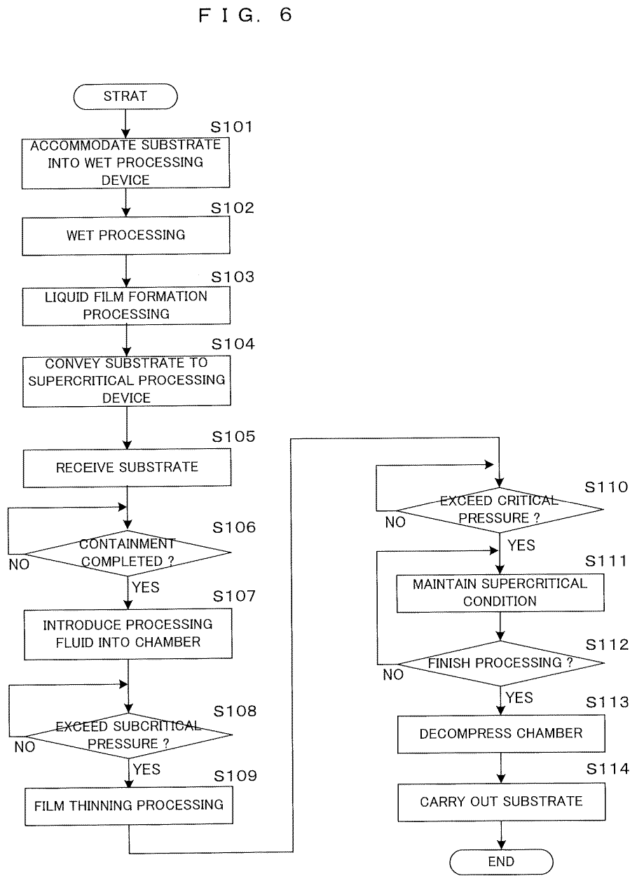

FIG. 6 is a flow chart outlining the processing performed by the substrate processing system according to the first embodiment. This substrate processing system 1 receives a substrate S to be processed and successively performs the wet processing using a processing fluid and the supercritical dry processing using a supercritical processing fluid. Specifically, the following Steps S101 to S114 are performed. The substrate S to be processed is accommodated into the wet processing device 2 constituting the substrate processing system 1 (Step S101). The substrate S may be directly carried in by an external conveying device or may be carried in from the external conveyor device via the conveyor robot 30.

The wet processing device 2 applies the wet processing to the substrate S using a predetermined processing fluid (Step S102). In this wet processing, a rinse liquid such as DIW (de-ionized water) is supplied to a surface Sa of the substrate S after a predetermined processing is performed by supplying a developer and a cleaning liquid. Accordingly, immediately after the wet processing is completed, the rinse liquid serving as an example of a “liquid” of the invention is adhering to the surface Sa of the substrate S. Thus, by supplying the organic solvent such as IPA to the substrate S after the wet processing, the rinse liquid adhering to the surface Sa of the substrate S is replaced by the organic solvent and a liquid-filled state filled with the organic solvent is created. That is, a liquid film LF is formed on the surface Sa of the substrate S (Step S103: liquid film formation processing).

The technical significance of the liquid film formation processing is as follows. For example, if the DIW is present in a pattern PT formed in the surface Sa of the substrate S, there is a possibility that the pattern PT collapses due to a surface tension of the DIW. Further, water marks may remain on the surface Sa of the substrate S due to incomplete drying. Furthermore, the surface Sa of the substrate S may undergo deterioration such as oxidation by being exposed to outside air. To avoid such a problem, the surface Sa of the substrate S is covered with the organic solvent. A liquid having a lower surface tension than the DIW and low in corrosivity to the substrate S, e.g. a liquid compatible with the DIW such as IPA and acetone, is suitably used as the organic solvent. A case where the DIW is used as the rinse liquid and the IPA is used as the organic solvent is described below.

The liquid film LF is formed on the surface Sa of the substrate S by the liquid film formation processing. The substrate S is conveyed from the wet processing device 2 to the supercritical processing device 4 by the substrate conveying device 3 while being kept in the liquid-filled state (Step S104).

The substrate S conveyed to the supercritical processing device 4 is accommodated into the processing chamber 412 while being kept in the liquid-filled state. Specifically, the substrate S is conveyed with the pattern formed surface (surface Sa) faced up and covered with the thin liquid film LF. As shown by dotted lines in FIG. 3, the lift pins 437 are lifted with the lid member 413 moved to the (−Y) side and the support tray 415 pulled out. The conveying device transfers the substrate S to the lift pins 437. By lowering the lift pins 437, the substrate S is placed on the support pins 417 positioned at the releasing position. Subsequent to that, the support pins 417 are moved to the sandwiching position to hold the substrate S. In this way, the reception of the substrate S by the support tray 415 is completed (Step S105).

If the support tray 415 and the lid member 413 integrally move in the (+Y) direction, the support tray 415 supporting the substrate S is accommodated into the processing space SP in the processing chamber 412 and the opening 421 is closed by the lid member 413.

If the accommodation of the substrate S is confirmed (“YES” in Step S106), carbon dioxide serving as a processing fluid is introduced in a gas phase state into the processing space SP with the liquid-filled state kept. That is, the introduction of the processing fluid into the processing chamber 412 is started (Step S107). Although outside air enters the processing space SP when the substrate S is carried in, this can be replaced by introducing the processing fluid in a gas phase. By further injecting the processing fluid in the gas phase, a pressure in the processing chamber 412 increases from an atmospheric pressure and the inside of the processing chamber 412 enters an atmospheric pressure state.

Note that the processing fluid is continuously discharged from the processing space SP in the process of introducing the processing fluid. That is, the processing fluid is discharged from the processing space SP by the fluid collector 455 also while the processing fluid is introduced by the fluid supplier 457. In this way, the processing fluid used for the processing is discharged into the processing space SP without staying, and impurities such as residues taken into the processing fluid are prevented from re-adhering to the substrate S.

If a supply amount of the processing fluid is more than a discharge amount, a density of the processing fluid in the processing space SP increases and a chamber inner pressure increases. Conversely, if the supply amount of the processing fluid is less than the discharge amount, the density of the processing fluid in the processing space SP decreases and the chamber inner pressure decreases. The processing fluid is supplied into and discharged from the processing chamber 412 based on a supply/discharge recipe prepared in advance. That is, the control device 9 adjusts supply/discharge timings, a flow rate and the like of the processing fluid by controlling the fluid supplier 457 and the fluid collector 455 based on the supply/discharge recipe. Further, the support pins 417 are reciprocated and the film thinning processing is performed according to a pressure change in the processing chamber 412.

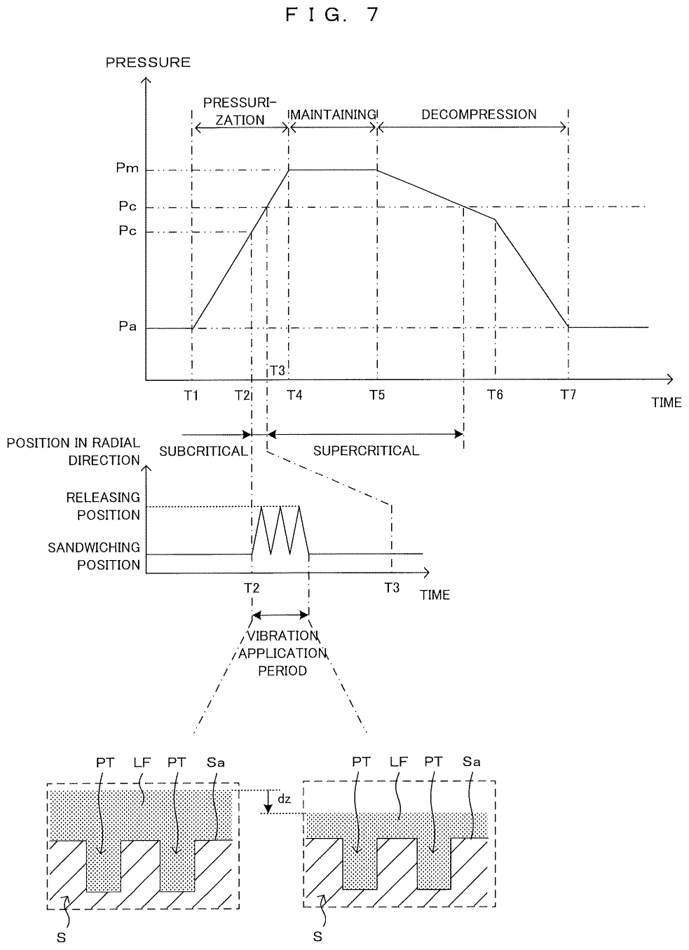

FIG. 7 is a chart showing a pressure change in the processing chamber, operations of support pins and an inside of the pattern. If the processing fluid is carbon dioxide, a temperature change during the processing is not very large since a critical temperature of the processing fluid is not very different from a room temperature. Here, a phenomenon is described, focusing on the chamber inner pressure, which notably changes. The introduction of the processing fluid is started and the internal pressure starts to increase at time T1 after the processing space SP is closed from a state where the processing space SP is open to atmospheric air and the internal pressure is an atmospheric pressure Pa.

The pressure of the processing fluid increases in the processing space SP. In this embodiment, pressurization is continued until the pressure in the processing chamber 412 exceeds a critical pressure Pc by way of a pressure Ps at which a subcritical state is reached (hereinafter, referred to as a “subcritical pressure”). Carbon dioxide is mixed with the IPA constituting the liquid film LF by supplying carbon dioxide, which is a processing fluid. In this way, the liquid film LF increases. However, if a surface tension of the mixture liquid (=IPA+carbon dioxide) decreases and the pressure in the processing chamber 412 reaches, for example, the vicinity of the subcritical pressure Ps, part of the mixture liquid constituting the liquid film LF drips down from the substrate S and the liquid film LF becomes thinner. Here, if vibration is applied to the substrate S when the surface tension decreases, part of the mixture liquid additionally drips down from the substrate S and the liquid film LF can be further thinned.

Accordingly, in this embodiment, when the pressure in the processing chamber 412 reaches the subcritical pressure Ps (“YES” in Step S108: time T2), a reciprocal movement command is given to the pin driver 417f from the supercritical processing controller 97. Then, as shown in a middle graph of FIG. 7, the pin driver 417f reciprocates the support pins 417 in the radial direction D. Along with this, the substrate S is repeatedly lifted and lowered to apply vibration in the vertical direction to the substrate S. In this way, the liquid film LF is thinned by a thickness dz while the liquid-filled state of the liquid film LF is maintained (Step S109: film thinning processing). Note that, the processing fluid enters the subcritical state in the chamber after time T3 at which the pressure in the processing chamber 412 reaches the subcritical pressure Ps. Therefore, it is necessary to set the end of a period for applying vibration, i.e. a vibration application period, before time T3. In contrast, the start of the vibration application period is not limited to time T2 and may be set at a timing at which the surface tension of the liquid film LF is sufficiently reduced. Further, the number of reciprocal movements of the support pins 417, i.e. a frequency, in the vibration application period is arbitrary.

After the film thinning processing is executed in this manner, the boosting is continued. Thus, at time T3 at which the critical pressure Pc is reached in the chamber, the processing fluid enters the supercritical state in the chamber. That is, the processing fluid transitions from the gas phase to the supercritical state due to a phase change in the processing space SP. By filling the processing space SP with the processing fluid in the supercritical state, the IPA covering the substrate S is replaced by the processing fluid in the supercritical state. The IPA and the like liberated from the surface of the substrate S is discharged from the processing chamber 412 together with the processing fluid while being dissolved in the processing fluid, and removed from the substrate S. That is, the processing fluid in the supercritical state has a function of replacing the IPA adhering to the substrate S and serving as a liquid to be replaced, and discharging the liquid to be replaced to the outside of the processing chamber 412.

By continuing a state where the processing space SP is filled with the processing fluid in the supercritical state for a predetermined time after time T3 at which the processing fluid reliably transitions into the supercritical state (Step S110, S111), the liquid to be replaced adhering to the substrate S can be completely replaced and discharged to the outside of the chamber. Note that although a chamber inner pressure Pm in the supercritical state is shown to be constant after the pressure boosting is continued until time T4 after time T3 in FIG. 7, the pressure may fluctuate within such a range as not to fall to or below the critical pressure Pc.

If the replacement of the liquid to be replaced by the processing fluid in the supercritical state is finished in the processing chamber 412 at time T4 (Step S112), the processing fluid in the processing space SP is discharged and the substrate S is dried. Specifically, the inside of the processing chamber 12 filled with the processing fluid in the supercritical state is decompressed by increasing the discharge amount of the fluid from the processing space SP (Step S113).

In a decompression process, the supply of the processing fluid may be stopped or a small amount of the processing fluid may be continuously supplied. By decompression from the state where the processing space SP is filled with the processing fluid in the supercritical state, the phase of the processing fluid changes from the supercritical state to the gas phase. By discharging the vaporized fluid to outside, the substrate S is dried. At this time, a decompression rate is so adjusted that a solid phase and a liquid phase are not created due to a sudden temperature drop. That is, decompression is performed at a relatively low decompression rate until time T6 at which the pressure reliably falls below the critical pressure Pc after decompression is started at time T5. In this way, the processing fluid in the processing space SP is directly vaporized from the supercritical state and discharged to outside.

At and after time T6 at which the processing fluid is completely vaporized, the decompression rate is increased, whereby decompression to the atmospheric pressure Pa is possible in a short time. By doing so, the processing fluid is not liquefied and the formation of a gas/liquid interface on the substrate S having the surface exposed after drying is avoided for an entire period from time T4 at which decompression is started to time T7 at which the pressure in the chamber falls to the atmospheric pressure Pa.

As just described, in the supercritical dry processing of this embodiment, the liquid adhering to the substrate can be efficiently replaced and prevented from remaining on the substrate S by changing the phase of the processing fluid to the gas phase and discharging the processing fluid after the processing space SP is filled with the processing fluid in the supercritical state. Moreover, the substrate can be dried while avoiding problems caused by the formation of the gas/liquid interface such as the contamination of the substrate and pattern collapse due to the adhesion of impurities.

The processed substrate S is delivered to a post-process (Step S114). That is, the support tray 415 is pulled out from the processing chamber 412 by moving the lid member 413 in the (−Y) direction, and the substrate S is transferred to the external conveying device via the transfer unit 43. At this time, the substrate S is in a dry state. Contents of the post-process are arbitrary. In this way, the processing for one substrate S is completed. If there is a substrate to be processed next, return is made to Step S101, a new substrate S is received and the above processing is repeated.

As described above, according to the first embodiment, since the substrate is dried by the processing fluid in the supercritical state after the liquid film LF is thinned, a drying time can be shortened.

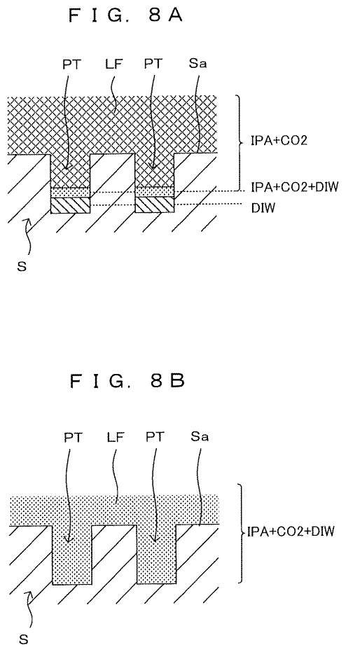

Further, the following functions and effects are obtained by the vibration application. These are described below with reference to FIGS. 8A and 8B.

FIG. 8A is a diagram schematically showing a problem occurring in the liquid film after the liquid film formation processing. Further, FIG. 8B is a diagram schematically showing how the above problem is solved by vibration application. After the liquid film formation processing (Step S103) is performed, part of the rinse liquid (DIW) may remain on the inner bottom surface of the pattern PT as shown in FIG. 8A. If the dry processing by the processing fluid in the supercritical state is applied to the substrate S while the liquid remaining in this way (hereinafter, referred to as a “remaining liquid”) is left unremoved, the following problem may occur. That is, the replacement of a liquid component constituting the liquid film and the processing fluid in the supercritical state tends to be incomplete. Thus, a measure for increasing a use amount of the processing fluid is thought to cover that problem. However, this leads to an increase of running cost and gives a large environmental burden on the society.

In contrast, in this embodiment, vibration is applied to the substrate S by performing the film thinning processing. Thus, the liquid (DIW) remaining in the pattern PT is transferred and diffused, and mixed with the mixture liquid (=IPA+carbon dioxide) constituting the liquid film LF. Therefore, the dry processing by the processing fluid in the supercritical state is performed in the absence of the remaining liquid on the inner bottom surface of the pattern PT, i.e. in a so-called remaining liquid-free state. As a result, a yield can be improved while the consumption of the processing fluid is reduced.

Further, part of the mixture liquid dripping down from the substrate S during the pressure boosting may adhere to the through holes 419, which may adversely affect dry performance. However, in this embodiment, the mixture liquid adhering to the through holes 419 can be caused to drop down and removed by the vibration application to the substrate S in the film thinning processing. As a result, the dry performance can be enhanced.

Further, in the first embodiment, reciprocal movements of the support pins 417 in the radial direction D are utilized to apply vibration to the substrate S. That is, the support pins 417 exhibit a vibration application function, besides a function of sandwiching the side edge part of the substrate S and holding the substrate S. Therefore, it is not necessary to add a configuration dedicated to the vibration application function, wherefore device cost can be reduced.

As described above, in the first embodiment, the DIW and the IPA respectively correspond to examples of a “liquid” and an “organic solvent” of the invention. Further, the subcritical pressure Ps and the critical pressure Pc respectively correspond to examples of a “first pressure” and a “second pressure” of the invention. Further, the surface Sa of the substrate S corresponds to an example of a “pattern formed surface” of the invention. Further, Steps S105, S106 correspond to an example of a “operation (a)” of the invention, Steps S107, S108 correspond to an example of a “operation (b)” of the invention, Steps S110, S111 correspond to an example of a “operation (c)” of the invention, and Step S109 corresponds to an example of a “operation (d)” of the invention. Further, the liquid film formation processing (Step S103) corresponds to an example of a “liquid film formation step” of the invention. Further, a period from time T1 to time T4 corresponds to an example of a “pressure boosting period” of the invention. Further, the supercritical processing controller 97 corresponds to an example of a “controller” of the invention.

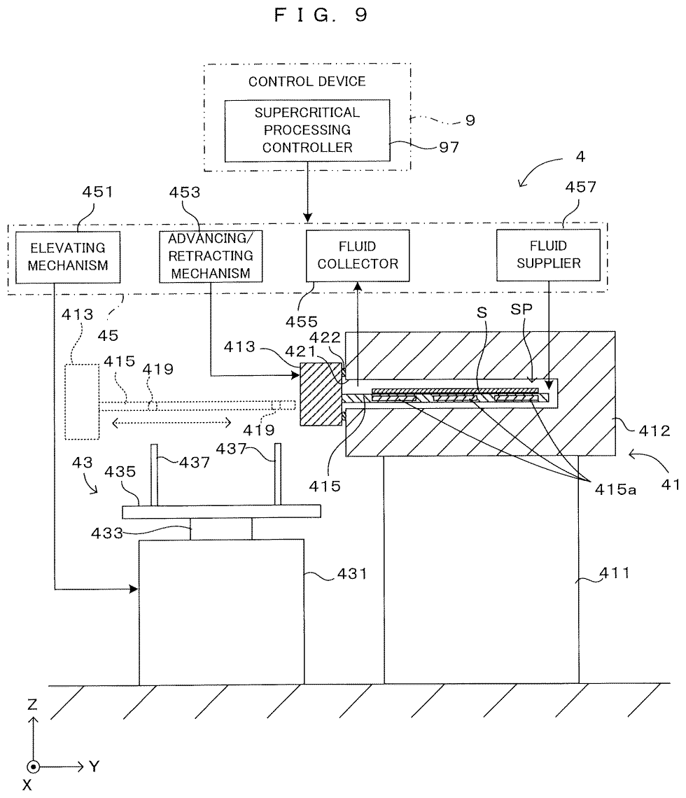

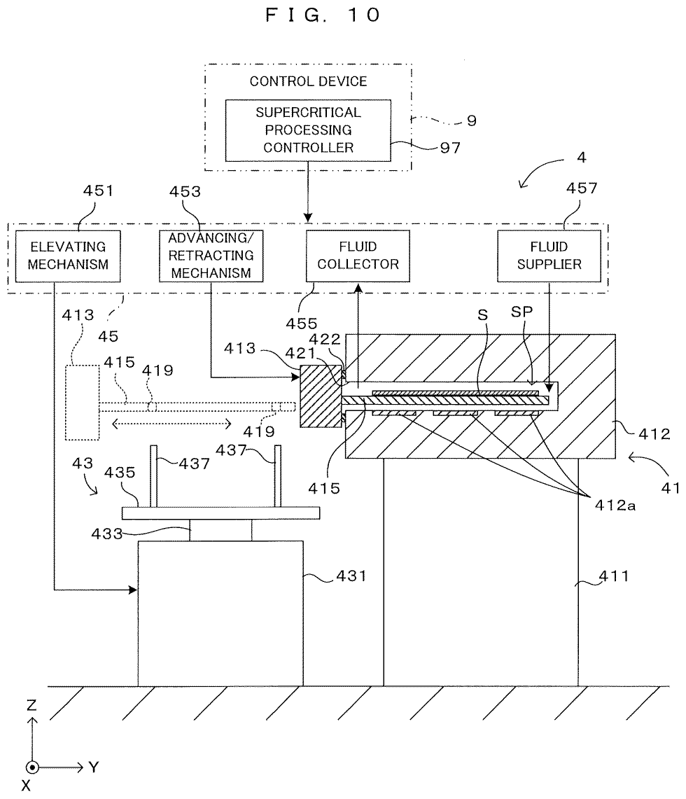

In the first embodiment, the support pins 417 are reciprocated in the D direction to perform the film thinning processing. That is, the support pins 417 and the pin driver 417f function as a “vibration applicator” of the invention, but the configuration of the vibration applicator is not limited to this. For example, vibration may be applied to the substrate S by a separately added configuration without performing the vibration application along the vertical direction Z by the support pins 417 (hereinafter, referred to as “vertical vibration application”). For example, the support tray 415 may be directly or indirectly vibrated by vibrators 415a (FIG. 9) or ultrasonic vibrators (FIG. 10), and the substrate S may be vibrated by the vibration of the support tray 415.

FIG. 9 is a diagram showing a second embodiment of the substrate processing device according to the invention. In this second embodiment, the vibrators 415a are mounted in the support tray 415. The vibrators 415a vibrate in response to a vibration command from the supercritical processing controller 97. As just described, in the second embodiment, the vibrators 415a correspond to an example of the “vibration applicator” of the invention. Here, the mounted positions of the vibrators 415a are not limited in the support tray 415 and the vibrators 415a may be mounted in the lid member 413.

FIG. 10 is a diagram showing a third embodiment of the substrate processing device according to the invention. In this third embodiment, the ultrasonic vibrators 412a are mounted in the processing chamber 412 to face the lower surface of the support tray 415. The ultrasonic vibrators 412a vibrate in response to a vibration command from the supercritical processing controller 97. As just described, in the third embodiment, the ultrasonic vibrators 412a correspond to an example of the “vibration applicator” of the invention.

As described above, also in the second and third embodiments, the film thinning processing (Step S109) is performed prior to the dry processing by the processing fluid in the supercritical state as in the first embodiment. Therefore, functions and effects such as the shortening of the drying time are obtained.

Note that the invention is not limited to the above embodiments and various changes other than the aforementioned ones can be made without departing from the gist of the invention. Although the film thinning processing is performed only once in applying the supercritical dry processing to one substrate S, the film thinning processing may be performed a plurality of times.

Further, various chemical substances used in the processings of the above embodiments are some examples, and various others can be used if these are consistent with the technical concept of the invention described above.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

This invention can be applied to techniques in general for drying a substrate by a processing fluid in a supercritical state in a chamber.

1. A substrate processing method for drying a substrate having a liquid film of an organic solvent formed in a liquid-filled state on a surface by a processing fluid in a supercritical state, the method comprising:
(a) accommodating the substrate into a processing chamber;
(b) boosting the processing chamber from an atmospheric pressure to a first pressure by supplying the processing fluid to the processing chamber, a subcritical state being reached at the first pressure;
(c) boosting the processing chamber to a second pressure by supplying the processing fluid to the processing chamber boosted to the first pressure, the supercritical state being reached at the second pressure; and
(d) reducing a film thickness of the liquid film while maintaining the liquid-filled state by applying vibration to the substrate in a pressure boosting period until the processing chamber enters the supercritical state from start of the operation (b).

2. The substrate processing method of claim 1, wherein:
the operation (a) includes:
(a-1) sandwiching and holding the substrate from a horizontal direction by a plurality of support pins by moving the plurality of support pins toward the substrate while continuously supporting the substrate by the plurality of support pins after a peripheral edge part of the substrate is supported from below by the plurality of support pins provided on a support tray; and
(a-2) moving the support tray into the processing chamber while holding the substrate by the plurality of support pins, and
the vibration is applied to the substrate in the operation (d) by reciprocating the plurality of support pins between a sandwiching position for sandwiching the substrate and a releasing position separated from the sandwiching position.

3. The substrate processing method of claim 1, wherein:
the operation (a) includes:
(a-3) placing the substrate on a support tray; and
(a-4) moving the support tray into the processing chamber with the substrate placed on the support tray, and
the vibration is applied to the substrate in the operation (d) by actuating a vibrator mounted in the support tray.

4. The substrate processing method of claim 1, wherein:
the operation (a) includes:
(a-3) placing the substrate on a support tray; and
(a-4) moving the support tray into the processing chamber with the substrate placed on the support tray, and
the vibration is applied to the substrate in the operation (d) by actuating an ultrasonic vibrator mounted in the processing chamber.

5. The substrate processing method according to claim 1, wherein:
the vibration is applied to the substrate in the subcritical state in the operation (d).

6. The substrate processing method according to claim 1, further comprising
(e) forming the liquid film on the pattern formed surface after a liquid adhering to the pattern formed surface is replaced by the organic solvent by supplying the organic solvent to the pattern formed surface adhered with the liquid before the operation (a),
wherein:
the liquid remaining in the pattern is mixed with the organic solvent in parallel with thinning of the liquid film by applying the vibration to the substrate in the operation (d).

7. A substrate processing device for drying a substrate having a liquid film of an organic solvent formed in a liquid-filled state on a surface by a processing fluid in a supercritical state, the device comprising:
a processing chamber configured to accommodate the substrate;
a fluid supplier configured to supply the processing fluid to the processing chamber;
a vibration applicator configured to apply vibration to the substrate accommodated in the processing chamber; and
a controller
configured to control the fluid supplier such that the processing chamber is boosted to a second pressure, the supercritical state being reached at the second pressure, by way of a first pressure, a subcritical state being reached at the first pressure, by supplying the processing fluid to the processing chamber in an atmospheric pressure state and
configured to control the vibration applicator to apply the vibration to the substrate while the processing chamber is boosted from an atmospheric pressure to the first pressure by applying the vibration to the substrate in a pressure boosting period until the processing chamber enters the supercritical state from start of the supply of the processing fluid.
